(19) United States
(12) Patent Application Publication
(10) Pub. No.: US 2025/0277171 A1
(43) Pub. Date: Sep. 4, 2025

(54) COMPOSITION FOR POST-CMP CLEANING

(71) Applicant: ENTEGRIS, INC., Billerica, MA (US)

(72) Inventors: Jun Liu, Newtown, CT (US); Michael White, Ridgefield, CT (US); Daniela White, Ridgefield, CT (US)

(21) Appl. No.: 19/065,632

(22) Filed: Feb. 27, 2025

Related U.S. Application Data
(60) Provisional application No. 63/559,259, filed on Feb. 29, 2024.

(51) Int. Cl. C11D 7/32; C11D 7/06; C11D 7/26; C11D 7/34; C11D 7/50; H01L 21/02

(52) U.S. Cl. CPC C11D 7/3227; C11D 7/06; C11D 7/265; C11D 7/3209; C11D 7/3218; C11D 7/3281; C11D 7/34; C11D 7/5022; H01L 21/02057

(57) ABSTRACT

The invention provides a composition comprising water, a chelating agent, and a pH adjustor. The invention also provides a method for removing residue from a surface of a microelectronic device substrate comprising contacting the surface of the microelectronic device substrate with a composition comprising water, a chelating agent, and a pH adjustor.

### BACKGROUND OF THE INVENTION

Microelectronic device substrates are used for preparing integrated circuit devices. The microelectronic device substrate includes a base, such as a silicon wafer having a highly planar surface. Onto the planar surface of the base, by way of many multiples of selective placement and removal steps, regions of electronically-functional features are added. The features are made by selectively adding and removing electronically-functional materials that exhibit insulative, conductive, or semi-conductive properties. These electronically-functional materials are placed as desired by use of processing materials that include photoresist, chemical etchant, and slurries that contain abrasive particles and chemical materials that aid in processing the surface.

One feature of integrated circuits is an array of conductive “interconnects,” which are also referred to as “lines” and “vias.” As part of an integrated circuit, conductive interconnects function to conduct electric current among and between various other electronic features. Each interconnect is in the form of a line or thin film of conductive material that extends within and is defined (in shape and size) by openings formed in an insulative material, such as a dielectric material. The dielectric material acts as an insulator between the very-closely spaced interconnect structures, and between the interconnect structures and other electronic features of the integrated circuit.

The types of materials used to produce the interconnect and the dielectric structures must be selected to properly function as part of an integrated circuit that performs at high efficiency and high reliability. For example, the conductive material of an interconnect should be of a type that does not migrate (e.g., diffuse) excessively into an adjacent dielectric material over time and during use in the presence of a voltage between the materials; such migration of interconnect material into an adjacent dielectric material is often referred to as “electromigration.” At the same time, the combined interconnect and dielectric material structure must have sufficient integrity, including at an interface between these materials, to result in a low level of defects and a high level of performance reliability. For example, a strong bond must exist at the interface to prevent separation of the dielectric material from the interconnect material during use.

Interconnects have in the past been commonly made of aluminum or tungsten, and more recently are made of copper. Copper has an advantageously high conductivity relative to aluminum and tungsten. In addition, copper-based interconnects offer better resistance to electromigration as compared to aluminum, thereby improving the reliability of the integrated circuit over time. Still, copper ions can tend to diffuse into silicon dioxide (SiO₂) under sufficient electrical bias, and adhesion of copper to silicon dioxide and to other dielectric materials can be poor.

To prevent these negative interactions of copper with a dielectric material, recent integrated circuit structures have been designed to include a barrier layer between a copper interconnect structure and an adjacent dielectric material. Barrier layers may be conductive materials or non-conductive materials, with examples including tantalum (Ta), tantalum nitride (TaNx), tungsten (W), titanium (Ti), titanium nitride (TiN), ruthenium (Ru), cobalt (Co), molybdenum (Mo), rhenium (Rh), and alloys thereof.

Processes of placing the various features of microelectronic devices onto a substrate include selectively placing insulative materials, semiconducting materials, and metal materials onto a substrate surface. Selective placement and removal of these materials may involve the use of process compositions such as photoresist, etchant, CMP slurries that contain abrasive and chemical materials, and plasma, among others, in steps such as photoresist coating, etching (e.g., wet etching, plasma etching), chemical-mechanical processing (a.k.a., chemical-mechanical polishing, chemical-mechanical planarization, or simply “CMP”), and ashing (“plasma ashing”).

Chemical-mechanical processing is a process by which very small amounts (thicknesses) of material are precisely removed from a surface of a microelectronic device substrate to polish (or “planarize”) the surface in preparation for a subsequent layer of material to be applied onto the processed surface. Chemical-mechanical processing involves highly precise mechanical abrasion of a surface, coupled with controlled interactions of chemical materials, such as oxidation, reduction, or chelation of a material that is present at or removed from the surface. Often, one type of material at the substrate surface is preferentially removed with high selectivity, in comparison to a reduced degree of removal of one or more other materials that are also present at the surface.

A CMP process involves applying a “slurry” to the surface along with contacting the surface with a moving CMP pad. The “slurry” is a liquid composition that contains microabrasive particles that provide mechanical abrasion of the surface, along with chemical materials that interact chemically with materials of the surface to facilitate selective removal of certain material from the surface and often to inhibit removal of another surface material. The slurry is applied to the surface while the CMP pad contacts the surface with the desired amount of pressure and motion to facilitate the abrasive and chemical removal of select materials from the surface. The combination of the mechanical action of the pad and abrasive particles moving against the surface, along with the action of the chemical ingredients, achieves desired removal, planarization, and polishing of the surface with desired low levels of defects and residue. The CMP process should produce a highly planar, low-defect, low-residue surface onto which a subsequent layer of a microelectronic device can be applied.

After a processing step (e.g., chemical-mechanic processing, etching, ashing, etc.), at least some amount of residue will be present at a surface of a substrate. Residue may include abrasive particles from a CMP slurry or other processing material, active chemical ingredients that are part of a CMP slurry (e.g., oxidizer, catalyst, and inhibitor) or other processing composition, a reaction product or by-product of a processing material or ingredient thereof, a chemical etchant, photoresist polymer or other solid processing ingredient, etc. Any such residue must be removed by cleaning the surface before performing a subsequent step of a microelectronic device fabrication process, to avoid defects or other potential sources of reduced device performance or reliability.

Certain methods and equipment commonly used for cleaning a surface of a microelectronic substrate, e.g., after an etching step, after a CMP step, or after another step used in fabricating a multi-layer microelectronic device, include those that involve a flow of cleaning solution over the surface in combination with megasonics, jetting, or brushing to remove residue and contaminants. Typical cleaning solutions are alkaline solutions, e.g., containing a suitable hydroxide compound along with other chemical materials that together remove residue from the surface by chemically interacting with the residue. The cleaning solution should be effective to remove a high percentage of residue from a surface, but also must be safe with respect to functional features of the substrate. A cleaning solution must not cause damage to those features. For example, a cleaning solution should not cause corrosion (i.e., oxidation) of a metal feature of a substrate, e.g., should not oxidize copper metal features of a substrate that may be present as interconnect or barrier features.

Thus, there remains a need in the art for new, useful, and improved cleaning compositions and specific ingredients are continually sought, especially for use with new microelectronic device structures such as those that may now include exposed surfaces of copper. The invention provides such cleaning compositions and uses. These and other advantages of the invention, as well as additional inventive features, will be apparent from the description of the invention provided herein.

### BRIEF SUMMARY OF THE INVENTION

The invention provides a composition comprising (a) water, (b) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and (c) a pH adjustor.

The invention also provides a kit comprising (a) a chelating agent and (b) a pH adjustor, as described herein.

The invention further provides a method for removing residue from a surface of a microelectronic device substrate, the method comprising (i) contacting the surface of the microelectronic device substrate with a composition comprising (a) water, (b) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and (c) a pH adjustor, and (ii) removing at least a portion of the residue from the surface of the microelectronic device substrate.

### BRIEF DESCRIPTION OF THE DRAWINGS

FIG. 1 is a graph showing the copper (Cu) etch rate (A/min) and cobalt (CO) etch rate (Å/min) exhibited by Cleaning Compositions 1A-1I of Example 1.

FIG. 2 is a graph showing the benzotriazole (BZA) removal rate (Å/min) exhibited by Cleaning Compositions 1A-1I of Example 1.

FIG. 3 is a graph showing the copper (Cu) etch rate (Å/min) and cobalt (CO) etch rate (Å/min) exhibited by Cleaning Compositions 2A-2H of Example 2.

FIG. 4 is a graph showing the benzotriazole (BZA) removal rate (Å/min) exhibited by Cleaning Compositions 2A-2H of Example 2.

FIG. 5 is a graph showing the copper (Cu) etch rate (Å/min) and cobalt (CO) etch rate (Å/min) exhibited by Cleaning Compositions 3A-3H of Example 3.

FIG. 6 is a graph showing the benzotriazole (BZA) removal rate (Å/min) exhibited by Cleaning Compositions 3A-3H of Example 3.

### DETAILED DESCRIPTION OF THE INVENTION

The invention provides a composition comprising (a) water, (b) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and (c) a pH adjustor.

The composition comprises water as a liquid carrier, i.e., a solute, of the non-aqueous components (e.g., the cleaning agent, the chelating agent, the pH adjustor, and other optional components). The water can be any suitable water and can be, for example, deionized water (DIW) or distilled water. Water can be present in the composition from any source, such as by being contained in a component that is combined with other components to produce a composition in the form of a concentrate; as water combined in pure form to other components of a concentrate; or as water added to a concentrate, e.g., at a point of use, as dilution water for the purpose of diluting a concentrate to a desirable concentration for use.

The composition can comprise any suitable amount of water. For example, the amount of water can be a particular amount for preparing a concentrate, or a particular amount to provide a desirable concentration for use, which concentration for use is generally a higher amount relative to the amount of water in a concentrate. In some embodiments, the composition exists as a concentrate and comprises from about 5 wt. % to about 90 wt. % water, based on the total weight of the composition, for example, from about 10 wt. % to about 90 wt. %, from about 20 wt. % to about 90 wt. %, from about 30 wt. % to about 90 wt. %, from about 40 wt. % to about 90 wt. %, from about 50 wt. % to about 90 wt. %, from about 60 wt. % to about 90 wt. %, from about 70 wt. % to about 90 wt. %, from about 5 wt. % to about 80 wt. %, from about 10 wt. % to about 80 wt. %, from about 20 wt. % to about 80 wt. %, from about 30 wt. % to about 80 wt. %, from about 40 wt. % to about 80 wt. %, from about 50 wt. % to about 80 wt. %, from about 60 wt. % to about 80 wt. %, or from about 70 wt. % to about 80 wt. % water based on the total weight of the composition. Upon dilution, the amount of water will be increased such that the composition comprises from about 70 wt. % to about 99.99 wt. % water, based on the total weight of the composition, for example, from about 70 wt. % to about 99.9 wt. %, from about 70 wt. % to about 99.5 wt. %, from about 70 wt. % to about 99 wt. %, from about 70 wt. % to about 98 wt. %, from about 70 wt. % to about 95 wt. %, from about 80 wt. % to about 99.99 wt. %, from about 80 wt. % to about 99.9 wt. %, from about 80 wt. % to about 99.5 wt. %, from about 80 wt. % to about 99 wt. %, from about 80 wt. % to about 98 wt. %, from about 80 wt. % to about 95 wt. %, from about 90 wt. % to about 99.99 wt. %, from about 90 wt. % to about 99.9 wt. %, from about 90 wt. % to about 99.5 wt. %, from about 90 wt. % to about 99 wt. %, from about 90 wt. % to about 98 wt. %, from about 90 wt. % to about 95 wt. %, from about 95 wt. % to about 99.99 wt. %, from about 95 wt. % to about 99.9 wt. %, from about 95 wt. % to about 99.5 wt. %, from about 95 wt. % to about 99 wt. %, or from about 95 wt. % to about 98 wt. % water based on the total weight of the composition. In some embodiments, the composition comprises from about 70 wt. % to about 99.9 wt. % water.

The composition comprises a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof. As used herein, multifunctional alcohol poly(oxypropylene)polyamine refers to a compound of formula:

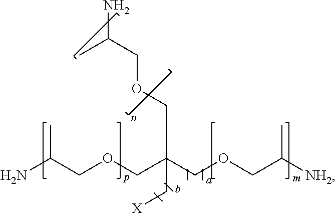

wherein a is 0 or 1, b is 0 or 1, m is an integer from 1 to 50 (e.g., 1 to 40 or 1 to 30), n is an integer from 1 to 50 (e.g., 1 to 40 or 1 to 30), p is an integer from 1 to 50 (e.g., 1 to 40 or 1 to 30), X is hydrogen, C₁₋₁₂ alkyl, C₂₋₁₂ alkenyl, aryl, or

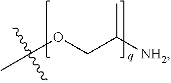

and q is an integer from 1 to 50 (e.g., 1 to 40 or 1 to 30). In some embodiments, the sum total of m, n, and p is an integer from 5 to 100 (e.g., from 10 to 90). Alternatively, or additionally, in some embodiments, (i) a is 0, b is 0, and X is hydrogen, (ii) a is 0, b is 0, and X is C₁₋₁₂ alkyl, (iii) a is 1, b is 0, and X is hydrogen, or (iv) a is 1, b is 0, and X is C_{I}-12 alkyl. For example, the multifunctional alcohol poly(oxypropylene)polyamine can be JEFFAMINE™ T-5000 Polyetheramine (commercially available from Hunstman), JEFFAMINE™ T-403 Polyetheramine (commercially available from Hunstman), or JEFFAMINE™ ST-404 Polyetheramine (commercially available from Hunstman).

As used herein, “alkyl” refers to a straight (linear) or branched, saturated, aliphatic group having the number of carbon atoms indicated (e.g., C₁₋₁₂, C₂₋₁₂, C₁₋₆, C₂₋₆, C₆₋₁₂, or C₆₋₁₀). For example, the term “alkyl” can include any number of carbons from one to twelve. Examples of alkyl groups include, but are not limited to, methyl, ethyl, 1-propyl, 2-propyl, 1-butyl, 2-methyl-1-propyl, 2-butyl, 2-methyl-2-propyl, 1-pentyl, 1-hexyl, 1-heptyl, 1-octyl, and the like.

As used herein, “alkenyl” refers to a straight (linear) or branched, unsaturated, aliphatic group having the number of carbon atoms (e.g., C₂₋₁₂, C₂₋₆, C₆₋₁₂, or C₆₋₁₀) indicated and at least one carbon-carbon double bond, sp2. For example, the term “alkenyl” can include any number of carbons from one to twelve. Alkenyl groups can have “cis” and “trans” orientations, or alternatively, “E” and “Z” orientations. Examples include, but are not limited to, vinyl, allyl. butenyl, pentenyl, and isomers thereof.

As used herein, “aryl” refers to a monovalent aromatic hydrocarbon group of 6-20 carbon atoms (C₆₋₂₀) derived by the removal of one hydrogen atom from a single carbon atom of a parent aromatic ring system. Aryl groups can be monocyclic, fused to form bicyclic or tricyclic groups, or linked by a bond to form a biaryl group. Representative aryl groups include phenyl, naphthyl, and biphenyl. Other aryl groups include benzyl, having a methylene linking group. Some aryl groups have from 6 to 12 ring members, such as phenyl, naphthyl, or biphenyl. Other aryl groups have from 6 to 10 ring members, such as phenyl or naphthyl.

The composition can comprise any suitable amount of the chelating agent. The composition can comprise about 20 wt. % or less of the chelating agent based on the total weight of the composition, for example, about 10 wt. % or less, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the chelating agent based on the total weight of the composition. Alternatively, or in addition, the composition can comprise about 0.005 wt. % or more of the chelating agent based on the total weight of the composition, for example, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of the chelating agent based on the total weight of the composition. Thus, the composition can comprise the chelating agent in any amount bounded by any two of the aforementioned endpoints, as appropriate.

For example, in some embodiments, the chelating agent can be present in the composition in an amount of about 0.005 wt. % to about 20 wt. % based on the total weight of the composition, e.g., about 0.005 wt. % to about 10 wt. %, about 0.005 wt. % to about 8 wt. %, about 0.005 wt. % to about 6 wt. %, about 0.005 wt. % to about 5 wt. %, about 0.005 wt. % to about 4 wt. %, about 0.005 wt. % to about 2 wt. %, about 0.005 wt. % to about 1 wt. %, about 0.005 wt. % to about 0.05 wt. %, about 0.05 wt. % to about 20 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.5 wt. % to about 20 wt. %, about 0.5 wt. % to about 10 wt. %, about 0.5 wt. % to about 8 wt. %, about 0.5 wt. % to about 6 wt. %, about 0.5 wt. % to about 5 wt. %, about 0.5 wt. % to about 4 wt. %, about 0.5 wt. % to about 2 wt. %, or about 0.5 wt. % to about 1 wt. % of the chelating agent based on the total weight of the composition. In some embodiments, the composition comprises about 1 wt. % to about 20 wt. % of the chelating agent based on the total weight of the composition. In certain embodiments, the composition comprises about 1 wt. % to about 10 wt. % of the chelating agent based on the total weight of the composition.

The composition comprises a pH adjustor. The pH adjustor can be any suitable compound capable of adjusting the pH of the composition to a range of about 7 to about 14. Exemplary pH adjustors include, but are not limited to bases such as, for example, potassium hydroxide, ammonium hydroxide (i.e., aqueous ammonia), and a tetraalkylammonium hydroxide compound having the formula NR⁴R⁵R⁶R⁷OH, wherein R⁴, R⁵, R⁶ and R⁷ are each independently chosen from hydrogen, straight-chain or branched C₁-C₆ alkyl (e.g., methyl, ethyl, propyl, butyl, pentyl, and hexyl) groups, C₁-C₆ hydroxyalkyl (e.g., hydroxymethyl, hydroxyethyl, hydroxypropyl, hydroxybutyl, hydroxypentyl, and hydroxyhexyl) groups, and substituted or unsubstituted C₆-C₁₀ aryl groups (e.g., benzyl groups). Exemplary pH adjustors further include, but are not limited to, tetraalkylammonium hydroxides such as, for example, tetramethylammonium hydroxide (TMAH), tetraethylammonium hydroxide (TEAH), tetrapropylammonium hydroxide (TPAH), tetrabutylammonium hydroxide (TBAH), tributylmethylammonium hydroxide (TBMAH), benzyltrimethylammonium hydroxide (BTMAH), choline hydroxide, ethyltrimethylammonium hydroxide, tris(2-hydroxyethyl)methyl ammonium hydroxide, and diethyldimethylammonium hydroxide. Additional pH adjustors include, but are not limited to, quaternary bases having the formula (PR⁸R⁹R¹⁰R¹¹)OH, wherein R⁸, R⁹, R¹⁰, and R¹¹ are each independently chosen from hydrogen, straight-chain C₁-C₆ alkyl (e.g., methyl, ethyl, propyl, butyl, pentyl, and hexyl) groups, branched C₁-C₆ alkyl groups, C₁-C₆ hydroxyalkyl (e.g., hydroxymethyl, hydroxyethyl, hydroxypropyl, hydroxybutyl, hydroxypentyl, and hydroxyhexyl) groups, substituted C₆-C₁₀ aryl groups, and unsubstituted C₆-C₁₀ aryl groups (e.g., benzyl groups), such as tetrabutylphosphonium hydroxide (TBPH), tetramethylphosphonium hydroxide, tetraethylphosphonium hydroxide, tetrapropylphosphonium hydroxide, benzyltriphenylphosphonium hydroxide, methyl triphenylphosphonium hydroxide, ethyl triphenylphosphonium hydroxide, and N-propyl triphenylphosphonium hydroxide. In some embodiments, the pH adjustor is selected from choline hydroxide, potassium hydroxide, tetraethylammonium hydroxide, methyl tris (hydroxyethyl)ammonium hydroxide, salts thereof, and combinations thereof. In certain embodiments, the pH adjustor is choline hydroxide.

The composition can comprise any suitable amount of the pH adjustor. Generally, the composition comprises the pH adjustor in an amount so as to maintain the pH of the composition in the range of about 7 to about 14.

The composition can have any suitable pH. Typically, the composition has a pH of about 7 or more, e.g., about 7.5 or more, about 8 or more, about 8.5 or more, about 9 or more, about 9.5 or more, about 10 or more, about 10.5 or more, or about 11 or more. Alternatively, or in addition, the composition can have a pH of about 14 or less, e.g., about 13.5 or less, about 13 or less, about 12.5 or less, or about 12 or less. Thus, the composition can have a pH bounded by any two of the aforementioned endpoints. For example, the composition can have a pH of about 7 to about 14, e.g., about 7 to about 13, about 7 to about 12, about 8 to about 14, about 8 to about 13, about 8 to about 12, about 9 to about 14, about 9 to about 13, about 9 to about 12, about 10 to about 14, about 10 to about 13, about 10 to about 12, about 11 to about 14, about 11 to about 13, or about 11 to about 12. In some embodiments, the composition has a pH of 8 to 14. In certain embodiments, the composition has a pH of 11 to 14. The pH of the composition can be adjusted using any suitable pH adjustor described herein in sufficient quantities to achieve such pH ranges.

In some embodiments, the composition further comprises a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof. In certain embodiments, the cleaning additive is selected from cysteine, cystine, 1,3,4-thiadiazole-2-methyl-5-thiol, salts thereof, and combinations thereof. In certain embodiments, the cleaning additive is cysteine.

The composition can comprise any suitable amount of the cleaning additive, when present. The composition can comprise about 10 wt. % or less of the cleaning additive, when present, based on the total weight of the composition, for example, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the cleaning additive, when present, based on the total weight of the composition. Alternatively, or in addition, the composition can comprise about 0.005 wt. % or more of the cleaning additive, when present, based on the total weight of the composition, for example, about 0.01 wt. % or more, 0.05 wt. % or more, about 0.1 wt. % or more, about 0.2 wt. % or more, or about 0.3 wt. % or more of the cleaning additive, when present, based on the total weight of the composition. Thus, the composition can comprise the cleaning additive in any amount bounded by any two of the aforementioned endpoints, as appropriate.

For example, in some embodiments, the cleaning additive can be present in the composition in an amount of about 0.005 wt. % to about 10 wt. % based on the total weight of the composition, e.g., about 0.005 wt. % to about 8 wt. %, about 0.005 wt. % to about 6 wt. %, about 0.005 wt. % to about 5 wt. %, about 0.005 wt. % to about 4 wt. %, about 0.005 wt. % to about 2 wt. %, about 0.005 wt. % to about 1 wt. %, about 0.005 wt. % to about 0.05 wt. %, about 0.01 wt. % to about 10 wt. %, about 0.01 wt. % to about 8 wt. %, about 0.01 wt. % to about 6 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, or about 0.1 wt. % to about 1 wt. % of the cleaning additive based on the total weight of the composition. In some embodiments, the composition comprises about 0.1 wt. % to about 1 wt. % of the cleaning additive based on the total weight of the composition. In certain embodiments, the composition comprises about 0.1 wt. % to about 0.5 wt. % of the cleaning additive based on the total weight of the composition.

In some embodiments, the composition further comprises a reducing agent. The reducing agent can be any suitable reducing agent capable of donating an electron to an electron recipient. In some embodiments, the composition comprises a reducing agent selected from diethyl hydroxylamine, ascorbic acid, hypophosphorous acid, sulfurous acid, salts thereof, and combinations thereof. In some embodiments, the composition comprises a reducing agent selected from diethyl hydroxylamine, ascorbic acid, hypophosphorous acid, salts thereof, and combinations thereof. In certain embodiments, the composition comprises diethyl hydroxylamine as a reducing agent.

The composition can comprise any suitable amount of the reducing agent, when present. The composition can comprise about 5 wt. % or less of the reducing agent, when present, based on the total weight of the composition, for example, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the reducing agent, when present, based on the total weight of the composition. Alternatively, or in addition, the composition can comprise about 0.005 wt. % or more of the reducing agent, when present, based on the total weight of the composition, for example, about 0.01 wt. % or more, 0.05 wt. % or more, about 0.1 wt. % or more, or about 0.5 wt. % or more of the reducing agent, when present, based on the total weight of the composition. Thus, the composition can comprise the reducing agent in any amount bounded by any two of the aforementioned endpoints, as appropriate.

For example, in some embodiments, the reducing agent can be present in the composition in an amount of about 0.005 wt. % to about 5 wt. % based on the total weight of the composition, e.g., about 0.005 wt. % to about 4 wt. %, about 0.005 wt. % to about 2 wt. %, about 0.005 wt. % to about 1 wt. %, about 0.005 wt. % to about 0.05 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 5 wt. %, about 0.1 wt. % to about 4 wt. %, about 0.1 wt. % to about 2 wt. %, or about 0.1 wt. % to about 1 wt. % of the reducing agent based on the total weight of the composition. In some embodiments, the composition comprises about 0.01 wt. % to about 5 wt. % of the reducing agent, when present, based on the total weight of the composition.

In some embodiments, the composition further comprises a corrosion inhibitor. The corrosion inhibitor can be any suitable corrosion inhibitor capable of reducing the corrosion rate of a material. In some embodiments, the composition comprises a corrosion inhibitor selected from dicyandiamide, morpholine, guanylurea, glycocyamine, salts thereof, and combinations thereof. In certain embodiments, the composition comprises a corrosion inhibitor selected from dicyandiamide, morpholine, salts thereof, and combinations thereof.

The composition can comprise any suitable amount of the corrosion inhibitor, when present. The composition can comprise about 5 wt. % or less of the corrosion inhibitor, when present, based on the total weight of the composition, for example, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the corrosion inhibitor, when present, based on the total weight of the composition. Alternatively, or in addition, the composition can comprise about 0.005 wt. % or more of the corrosion inhibitor, when present, based on the total weight of the composition, for example, about 0.01 wt. % or more, 0.05 wt. % or more, about 0.1 wt. % or more, or about 0.5 wt. % or more of the corrosion inhibitor, when present, based on the total weight of the composition. Thus, the composition can comprise the corrosion inhibitor in any amount bounded by any two of the aforementioned endpoints, as appropriate.

For example, in some embodiments, the corrosion inhibitor can be present in the composition in an amount of about 0.005 wt. % to about 5 wt. % based on the total weight of the composition, e.g., about 0.005 wt. % to about 4 wt. %, about 0.005 wt. % to about 2 wt. %, about 0.005 wt. % to about 1 wt. %, about 0.005 wt. % to about 0.05 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 5 wt. %, about 0.1 wt. % to about 4 wt. %, about 0.1 wt. % to about 2 wt. %, or about 0.1 wt. % to about 1 wt. % of the corrosion inhibitor based on the total weight of the composition. In some embodiments, the composition comprises about 0.01 wt. % to about 5 wt. % of the corrosion inhibitor, when present, based on the total weight of the composition.

In some embodiments, the composition further comprises one or more additional complexing agents. The complexing agent can be any suitable compound capable of forming a complex (e.g., chelating) with another component (e.g., metal, compound, ion, etc.). For example, the additional complexing agent can include amino acids (e.g., glycine, alanine, serine, arginine, histidine, lysine, glutamic acid, serine, threonine, and proline), phosphonates (e.g., 1-hydroxyethylidene-1,1-diphosphonic acid (HEDP), 1,5,9-triazacyclododecane-N,N′,N″-tris(methylenephosphonic acid) (DOTRP), 1,4,7,10-tetraazacyclododecane-N,N′,N″,N′″-tetrakis(methylenep-hosphonic acid) (DOTP), nitrilotris(methylene)triphosphonic acid, diethylenetriaminepentakis(methylenephosphonic acid) (DETAP), aminotri(methylenephosphonic acid), bis(hexamethylene)triamine pentamethylene phosphonic acid, 1,4,7-triazacyclononane-N,N′,N″-tris(methylenephosphonic acid (NOTP), hydroxyethyldiphosphonate, nitrilotris(methylene)phosphonic acid, 2-phosphono-butane-1,2,3,4-tetracarboxylic acid, carboxyethyl phosphonic acid, aminoethyl phosphonic acid, glyphosate, and ethylene diamine tetra(methylenephosphonic acid) phenylphosphonic acid), carboxylic acids (e.g., oxalic acid, succinic acid, maleic acid, malic acid, malonic acid, adipic acid, phthalic acid, citric acid, sodium citrate, potassium citrate, ammonium citrate, tricarballylic acid, dimethylolpropionic acid, trimethylolpropionic acid, tartaric acid, glucuronic acid, and 2-carboxypyridine), sulfonic acids (e.g., 4,5-dihydroxy-1,3-benzenedisulfonic acid disodium salt), salts thereof, and combinations thereof. In some embodiments, the composition comprises one or more additional complexing agents selected from glycine, alanine, serine, arginine, histidine, lysine, glutamic acid, serine, threonine, proline, 1-hydroxyethylidene-1,1-diphosphonic acid, 1,5,9-triazacyclododecane-N,N′,N″-tris(methylenephosphonic acid), 1,4,7,10-tetraazacyclododecane-N,N′,N″,N′″-tetrakis(methylenep-hosphonic acid), nitrilotris(methylene)triphosphonic acid, diethylenetriaminepentakis(methylenephosphonic acid), aminotri(methylenephosphonic acid), bis(hexamethylene)triamine pentamethylene phosphonic acid, 1,4,7-triazacyclononane-N,N′,N″-tris(methylenephosphonic acid, hydroxyethyldiphosphonate, nitrilotris(methylene)phosphonic acid, 2-phosphono-butane-1,2,3,4-tetracarboxylic acid, carboxyethyl phosphonic acid, aminoethyl phosphonic acid, glyphosate; ethylene diamine tetra(methylenephosphonic acid) phenylphosphonic acid, oxalic acid, succinic acid, maleic acid, malic acid, malonic acid, adipic acid, phthalic acid, citric acid, tricarballylic acid, dimethylolpropionic acid, trimethylolpropionic acid, tartaric acid, glucuronic acid, 2-carboxypyridine, 4,5-dihydroxy-1,3-benzenedisulfonic acid, and salts thereof. In certain embodiments, the composition comprises one or more additional complexing agents selected from oxalic acid, citric acid, 1-hydroxyethylidene-1,1-diphosphonic acid, and salts thereof.

The composition can comprise any suitable amount of the one or more additional complexing agents, when present. The composition can comprise about 5 wt. % or less of the one or more additional complexing agents, when present, based on the total weight of the composition, for example, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the one or more additional complexing agents, when present, based on the total weight of the composition. Alternatively, or in addition, the composition can comprise about 0.005 wt. % or more of the one or more additional complexing agents, when present, based on the total weight of the composition, for example, about 0.01 wt. % or more, 0.05 wt. % or more, about 0.1 wt. % or more, or about 0.5 wt. % or more of the one or more additional complexing agents, when present, based on the total weight of the composition. Thus, the composition can comprise the one or more additional complexing agents in any amount bounded by any two of the aforementioned endpoints, as appropriate.

For example, in some embodiments, the one or more additional complexing agents can be present in the composition in an amount of about 0.005 wt. % to about 5 wt. % based on the total weight of the composition, e.g., about 0.005 wt. % to about 4 wt. %, about 0.005 wt. % to about 2 wt. %, about 0.005 wt. % to about 1 wt. %, about 0.005 wt. % to about 0.05 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 5 wt. %, about 0.1 wt. % to about 4 wt. %, about 0.1 wt. % to about 2 wt. %, or about 0.1 wt. % to about 1 wt. % of the additional complexing agent based on the total weight of the composition. In some embodiments, the composition comprises about 0.01 wt. % to about 1 wt. % of the one or more additional complexing agents, when present, based on the total weight of the composition.

In some embodiments, the composition further comprises one or more water-miscible solvents. Exemplary water-miscible solvents include, but are not limited to, alcohols, glycols, and glycol ethers, including, but not limited to, methanol, ethanol, isopropanol, butanol, and higher alcohols (such as C₂-C₄ diols and C₂-C₄ triols), tetrahydrofurfuryl alcohol (THFA), halogenated alcohols (e.g., 3-chloro-1,2-propanediol, 3-chloro-1-propanethiol, 1-chloro-2-propanol, 2-chloro-1-propanol, 3-chloro-1-propanol, 3-bromo-1,2-propanediol, 1-bromo-2-propanol, 3-bromo-1-propanol, 3-iodo-1-propanol, 4-chloro-1-butanol, and 2-chloroethanol), dichloromethane, chloroform, acetic acid, propionic acid, trifluoroacetic acid, tetrahydrofuran N-methylpyrrolidinone (NMP), cyclohexylpyrrolidinone, N-octylpyrrolidinone, N-phenylpyrrolidinone, methyldiethanolamine, methyl formate, dimethyl formamide (DMF), dimethylsulfoxide (DMSO), tetramethylene sulfone (sulfolane), diethyl ether, phenoxy-2-propanol (PPh), propriophenone, ethyl lactate, ethyl acetate, ethyl benzoate, acetonitrile, acetone, ethylene glycol, propylene glycol (PG), 1,3-propanediol, dioxane, butyryl lactone, butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, propylene glycol monobutyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, ethylene glycol monophenyl ether, diethylene glycol monophenyl ether hexaethylene glycol monophenylether, dipropylene glycol methyl ether acetate, tetraethylene glycol dimethyl ether (TEGDE), dibasic ester, glycerine carbonate, N-formyl morpholine, triethyl phosphate, and combinations thereof. In certain embodiments, the composition comprises a water-miscible solvent selected from triethylene glycol monobutyl ether, propylene glycol n-butyl ether, propylene glycol monobutyl ether, dimethyl sulfoxide, diethylene glycol monophenyl ether, diethylene glycol monobutyl ether, and combinations thereof.

The composition can comprise any suitable amount of the one or more water-miscible solvents, when present. The composition can comprise about 5 wt. % or less of the one or more water-miscible solvents, when present, based on the total weight of the composition, for example, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the one or more water-miscible solvents, when present, based on the total weight of the composition. Alternatively, or in addition, the composition can comprise about 0.005 wt. % or more of the one or more water-miscible solvents, when present, based on the total weight of the composition, for example, about 0.01 wt. % or more, 0.05 wt. % or more, about 0.1 wt. % or more, or about 0.5 wt. % or more of the one or more water-miscible solvents, when present, based on the total weight of the composition. Thus, the composition can comprise the one or more water-miscible solvents in any amount bounded by any two of the aforementioned endpoints, as appropriate.

For example, in some embodiments, the one or more water-miscible solvents can be present in the composition in an amount of about 0.005 wt. % to about 5 wt. % based on the total weight of the composition, e.g., about 0.005 wt. % to about 4 wt. %, about 0.005 wt. % to about 2 wt. %, about 0.005 wt. % to about 1 wt. %, about 0.005 wt. % to about 0.05 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 5 wt. %, about 0.1 wt. % to about 4 wt. %, about 0.1 wt. % to about 2 wt. %, or about 0.1 wt. % to about 1 wt. % of the water-miscible solvents based on the total weight of the composition. In some embodiments, the composition comprises about 0.01 wt. % to about 1 wt. % of the one or more water-miscible solvents, when present, based on the total weight of the composition.

In some embodiments, the compositions further comprise one or more surfactants (e.g., a nonionic surfactant, a cationic surfactant, or an anionic surfactant). In certain embodiments, the composition further comprises a nonionic surfactant. As used herein the term “surfactant” refers to an organic compound that lowers the surface tension (or interfacial tension) between two liquids or between a liquid and a solid, typically an organic amphiphilic compound that contains a hydrophobic group (e.g., a hydrocarbon (e.g., alkyl) “tail”) and a hydrophilic group. When present, the non-ionic surfactants for use in the compositions described herein include, but are not limited to, polyoxyethylene lauryl ether, dodecenylsuccinic acid monodiethanol amide, ethylenediamine tetrakis (ethoxylate-block-propoxylate) tetrol, polyethylene glycols, polypropylene glycols, polyethylene or polypropylene glycol ethers, block copolymers based on ethylene oxide and propylene oxide, polyoxypropylene sucrose ether, t-octylphenoxypolyethoxyethanol, 10-ethoxy-9,9-dimethyldecan-1-amine, Polyoxyethylene (9) nonylphenylether, branched Polyoxyethylene (40) nonylphenylether, branched dinonylphenyl polyoxyethylene, nonylphenol alkoxylates, polyoxyethylene sorbitol hexaoleate, polyoxyethylene sorbitol tetraoleate, polyethylene glycol sorbitan monooleate, sorbitan monooleate, alcohol alkoxylates, alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives, siloxane modified polysilazanes, silicone-polyether copolymers, ethoxylated fluorosurfactants, and combinations thereof.

In some embodiments, the composition further comprises one or more water-dispersible or water-soluble polymers. Such polymers, when present, include but are not limited to methacrylic acid homopolymer, methacrylic acid copolymers with, for example, acrylamidomethylpropane sulfonic acid and maleic acid, maleic acid and vinyl ether copolymer; poly(vinylpyrrolidone) and vinyl acetate copolymer, phosphonated polyethyleneglycol oligomers, poly(acrylic acid) (PAA), poly(acrylamide), poly(vinyl acetate), poly(ethylene glycol) (PEG), polypropylene glycol (PPG), poly(styrene sulfonic acid), poly(vinyl sulfonic acid), poly(vinyl phosphonic acid), poly(vinyl phosphoric acid), poly(ethyleneimine), poly(propyleneimine), polyallylamine, polyethylene oxide (PEO), polyvinyl pyrrolidone (PVP), PPG-PEG-PPG block copolymers, PEG-PPG-PEG block copolymers, poly(vinyl alcohol), poly(hydroxyethyl)acrylate, poly(hydroxyethyl)methacrylate, hydroxyethyl cellulose, methylhydroxyethyl cellulose, hydroxypropyl cellulose, methylhydroxypropyl cellulose, xanthan gum, potassium alginate, pectin, carboxymethylcellulose, glucosamine, poly(diallyldimethylammonium) chloride, PEGylated (i.e., polyethyleneglycol-ated) methacrylate/acrylate copolymers, poly MADQuat (poly(2-methacryloxyethyltrimethylammonium chloride-CAS Number 26161-33-1) and copolymers thereof, dimethylaminomethacrylate polymers and copolymers thereof, trimethylammonium methylmethacrylate polymers and copolymers thereof, and combinations thereof. The copolymers above may be random or block copolymers. When present, the amount of the one or more water-dispersible or water-soluble polymers in the composition is in a range from about 0.0001 wt. % to about 5 wt. % based on the total weight of the composition.

In some embodiments, the composition further comprises a biocide. The biocide can be any suitable biocide. For example, the biocide can be an isothiazolinone-based biocide such as Kordek MLX™ (DuPont, Wilmington, DE). In certain embodiments, the biocide is 5-chloro-2-methyl-4-isothiazolin-3-one, 2-methyl-4-isothiazolin-3-one, benzisothiazolone, 1,2-benzisothiazol-3[2H]-one, methylisothiazolinone, methylchloroisothiazolinone, or a combination thereof. The composition can comprise any suitable amount of the biocide. For example, the composition can comprise about 0.001 wt. % to about 0.2 wt. % of the biocide.

In some embodiments, the invention provides a composition comprising (a) water, (b) a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof, (c) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and (d) a pH adjustor.

In some embodiments, the invention provides a composition comprising (a) water, (b) a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof, (c) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, (d) a pH adjustor, and (e) a reducing agent selected from diethyl hydroxylamine, ascorbic acid, hypophosphorous acid, sulfurous acid, salts thereof, and combinations thereof.

In some embodiments, the invention provides a composition comprising (a) water, (b) a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof, (c) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, (d) a pH adjustor, and (e) a corrosion inhibitor selected from dicyandiamide, morpholine, guanylurea, glycocyamine, salts thereof, and combinations thereof.

In some embodiments, the invention provides a composition comprising (a) water, (b) a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof, (c) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, (d) a pH adjustor, and (e) a water-miscible solvent selected from triethylene glycol monobutyl ether, propylene glycol n-butyl ether, propylene glycol monobutyl ether, dimethyl sulfoxide, diethylene glycol monophenyl ether, diethylene glycol monobutyl ether, and combinations thereof.

The compositions of the invention can be prepared and then sold in the form a concentrate, which contains water at a relatively low amount, and, consequently, a relatively concentrated amount of non-aqueous ingredients. The concentrate can be prepared commercially to be sold and transported while containing the concentrated amount of non-aqueous ingredients and relatively reduced amount of water, and to be eventually diluted by a purchaser of the concentrate at a point of use. The amounts of the different non-aqueous ingredients in the concentrate are amounts that, upon dilution of the concentrate, will result in desired amounts of those non-aqueous ingredients being present in the composition as ultimately utilized.

The composition of the invention can be easily prepared by simple addition of the respective ingredients and mixing to homogeneous condition, such as a solution. Furthermore, a composition may be readily formulated as single-package formulations or multi-part formulations that are mixed at or before the point of use, e.g., the individual parts of the multi-part formulation may be mixed by a user either at a processing tool (cleaning apparatus) or in a storage tank upstream of the processing tool.

Thus, the composition can be supplied as a one-package system comprising water, chelating agent, and pH adjustor, and/or any optional additive. Alternatively, the composition of the invention can be supplied as a two-package system. The two-package system allows for the adjustment of composition characteristics by changing the blending ratio of the two packages. Similarly, a three-, four-, or more package system can be utilized in connection with the invention, wherein each of multiple containers contains different components of the inventive composition, one or more optional additives, and/or one or more of the same components in different concentrations.

Accordingly, in another aspect of the invention relates to a kit including, in two or more containers, various components of the composition described herein, suitable for storing and shipping the compositions and may include, for example, NOWPAK™ containers (Entegris, Inc., Billerica, MA, USA). Thus, the invention also provides a kit comprising, in two or more containers, two or more of:
(a) water,
(b) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and
(c) a pH adjustor.

In some embodiments, the kit comprises, in two or more containers, two or more of:
(a) water,
(b) a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof,
(c) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and
(d) a pH adjustor.

In certain embodiments, the kit comprises, in two or more containers, two or more of:
(a) water,
(b) a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof,
(c) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof,
(d) a pH adjustor,
(e) a reducing agent selected from diethyl hydroxylamine, ascorbic acid, hypophosphorous acid, sulfurous acid, salts thereof, and combinations thereof,
(f) a corrosion inhibitor selected from dicyandiamide, morpholine, guanylurea, glycocyamine, salts thereof, and combinations thereof, and
(g) a water-miscible solvent selected from triethylene glycol monobutyl ether, propylene glycol n-butyl ether, propylene glycol monobutyl ether, dimethyl sulfoxide, diethylene glycol monophenyl ether, diethylene glycol monobutyl ether, and combinations thereof.

The invention further provides a method for removing residue from a surface of a microelectronic device substrate, the method comprising (i) contacting the surface of the microelectronic device substrate with a composition comprising (a) water, (b) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and (c) a pH adjustor, and (ii) removing at least a portion of the residue from the surface of the microelectronic device substrate.

As used herein, the term “residue” (which is inclusive of a “contaminant”) refers to any material that is a chemical or particulate material that remains present at a surface of a microelectronic device substrate after a processing step used in the fabrication of a microelectronic device, for example, processing steps including plasma etching, plasma ashing (to remove photoresist from an etched wafer), chemical-mechanical processing, wet etching, etc. The residue may be any non-aqueous chemical material that is part of a processing composition used in the processing step, such as a chemical etchant, a photoresist, a CMP slurry, etc. The residue may alternately be a substance that is derived from a material of the processing composition during a processing step. Examples of these types of residues include non-aqueous, particulate or non-particulate, chemical or abrasive materials (e.g., abrasive particles, surfactant, oxidizer, corrosion inhibitor, catalyst) that remain at a surface of the substrate after processing. The residue may be originally present in a material such as a CMP slurry or an etching composition, such as a solid abrasive particle or chemical material present in a CMP abrasive slurry. Alternately, or additionally, a residue may be a by-product or a reaction product (in particulate (e.g., agglomerate or precipitate) or non-particulate form) that is generated during processing, e.g., a by-product or reaction product of a chemical present in a processing composition such as CMP slurry or wet etching composition, or a chemical that is present, used during, or produced during a plasma etching or a plasma ashing process.

The term “post-CMP residue” refers to residue that is present at an end of a CMP processing step, for example, a particle or chemical material that is present in or derived from a CMP slurry. Specific examples of post-CMP residues include, but are not limited to, abrasive particles (e.g., silica-containing or silica-based abrasive particles, metal oxide (e.g., alumina) particles, ceria or ceria-based particles, and the like), chemicals that are originally present in the slurry (e.g., an oxidizer, catalyst, surfactant, inhibitor, complexing agent, etc.), a metal, metal oxide, or metal complex that is derived from a metal material removed from the substrate surface being processed, or a reaction product or complex produced using a chemical of the slurry with another chemical of the slurry or with a chemical material derived from the substrate (e.g., a metal ion, pad particles, or any other material that is a product of the CMP process).

A “post-etch residue” refers to a material remaining following a gas-phase plasma etching process, e.g., back-end-of-line (“BEOL”) dual damascene processing, or wet etching processes. A post-etch residue may be organic, organometallic, organosilicic, or inorganic in nature, for example, silicon-containing material, carbon-based organic material, and etch gas residues such as oxygen residues and fluorine residues.

A “post-ash residue” refers to material remaining following oxidative or reductive plasma ashing to remove hardened photoresist and/or bottom anti-reflective coating (BARC) materials. The post-ash residue may be organic, organometallic, organosilicic, or inorganic in nature.

As noted above, the present invention relates to compositions which are useful in a cleaning method that removes residue from a surface of a microelectronic device substrate that has residue thereon. The compositions contain an aqueous carrier (i.e., water) along with a combination of non-aqueous ingredients as set forth herein. In certain embodiments, the compositions, before being used in a cleaning process, are homogeneous solutions that comprise, consist of, or consist essentially of water and dissolved non-aqueous ingredients, in the absence of any solid or suspended materials such as solid abrasive particles, agglomerates, coagulates, etc.

The compositions as described herein are useful for cleaning microelectronic devices and precursors thereof, specifically including microelectronic device substrates, meaning semiconductor wafers that include on a surface one or more microelectronic devices or precursors thereof that are in the process of being fabricated into final, completed, and functional microelectronic devices.

As used herein, a microelectronic device is a device that includes electrical circuits and related structures of very small (e.g., micron-scale or smaller) dimensions formed thereon. Exemplary microelectronic devices include flat panel displays, integrated circuits, memory devices, solar panels, photovoltaics, and microelectromechanical systems (MEMS). A microelectronic device substrate is a structure such as a wafer (e.g., semiconductor wafer) that includes one or more microelectronic devices or precursors thereof, in a state of being prepared to form a final microelectronic device.

The compositions and methods described herein are useful to clean any of various forms of microelectronic devices, at any stage of processing. The compositions and method of the invention are effective to remove at least a portion of the residue from the surface of the microelectronic device substrate. In some embodiments, the compositions and methods described herein are effective to remove a substantial amount (e.g., at least 50% or more, at least 60% or more, or at least 70% or more) of residue from the surface, relative to an amount that is initially present at the surface before the cleaning step. In certain embodiments, a high percentage of residue that is present at a substrate surface can be successfully removed from the surface by use of compositions (i.e., cleaning compositions) and methods described herein. For example, the compositions (i.e., cleaning compositions) and methods described herein can be effective, in a cleaning step, to remove at least 80% of residue present on a surface of the substrate prior to residue removal by a cleaning step, at least 85% of residue, at least 90% of residue, at least 95% of residue, or at least 99% of residue at least 95 percent of residue, or at least 99 percent of residue from the surface, relative to an amount that is initially present at the surface before the cleaning step.

Methods and equipment for measuring residue at a surface of a microelectronic device substrate are well known. Cleaning efficiency may be rated based on a reduction of an amount (e.g., number) of residue particles present on a microelectronic device surface after cleaning, compared to the amount (e.g., number) of residue particles present before cleaning. For example, pre- and post-cleaning analysis may be carried out using an atomic force microscope. Residue particles on a surface may be registered as a range of pixels. A histogram (e.g., a Sigma Scan Pro) may be applied to filter the pixels in a certain intensity, e.g., 231-235, and the number of residue particles counted. The amount of residue particle removal, i.e., cleaning efficiency, may be calculated using the following ratio: (Number of PreClean Residue Particles on a Surface-Number of PostClean Residue Particles on the Surface)/(Number of PreClean Residue Particles on the Surface).

Alternately, cleaning efficiency may be considered as a percentage of a total amount of a substrate surface that is covered by residue particulate matter before as compared to after cleaning. For example, an atomic force microscope may be programmed to perform a z-plane scan to identify topographic areas of interest above a certain height threshold, and then calculate the area of the total surface covered by the areas of interest. A reduced amount of area determined to be areas of interest, after cleaning, indicates a more efficacious cleaning composition and cleaning process.

In a cleaning step, such as a post-CMP residue cleaning step, a cleaning composition may be used with any of a variety of known, conventional, commercially available cleaning tools such as megasonics and brush scrubbing, including, but not limited to, Verteq single wafer megasonic Goldfinger, OnTrak systems DDS (double-sided scrubbers), SEZ or other single wafer spray rinse, Applied Materials Mirra-MESA™/REFLEXION™/REFLEXION LK™, and Megasonic batch wet bench systems, and Ebara Technologies, Inc. products such as 300 mm models (FREX300S2 and FREX300X3SC) and the 200 mm CMP system (FREX200M).

Conditions and timing of a cleaning step can be as desired, and may vary depending on the type of substrate and residue. In use of a composition for cleaning post-CMP residue, post-etch residue, post-ash residue or contaminants from a microelectronic device substrate having the same thereon, the compositions (i.e., cleaning compositions) may be contacted with the substrate surface for a time of from about 1 second to about 20 minutes, e.g., from about 5 seconds to 10 minutes, or from about 15 seconds to about 5 minutes, at temperature in a range of from about 20° C. to about 90° C., or about 20° C. to about 50° C. Such contacting times and temperatures are illustrative, and any other suitable time and temperature conditions may be useful if efficacious to at least partially clean an initial amount of residue from a surface.

Following the desired level of cleaning of a device substrate surface, the compositions (i.e., cleaning compositions) used in a cleaning step may be readily removed from the device surface, as may be desired and efficacious in a given end use application. For example, removal may be performed by use of a rinse solution that includes deionized water. Thereafter, the device may be processed as desired, such as by being dried (e.g., using nitrogen or a spin-dry cycle), followed by subsequent processing of the cleaned and dried device surface.

In other more general or specific methods, a microelectronic device substrate may first be subjected to a processing step that includes by any one or more of CMP processing, plasma etching, wet etching, plasma ashing, or the like, followed by a cleaning step that includes cleaning the substrate surface with the composition of the present invention. At the end of the first processing step, residue (e.g., post-etch residue, post-CMP residue, post ash residue, etc.) will be present at a surface of the substrate. The cleaning step, using a compositions (i.e., cleaning compositions) as described, will be effective to clean a substantial amount of the residue from the microelectronic device surface.

The invention further provides a method for removing residue from a surface of a microelectronic device substrate, the method comprising (i) contacting the surface of the microelectronic device substrate with a composition comprising (a) water, (b) a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof, (c) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and (d) a pH adjustor, and (ii) removing at least a portion of the residue from the surface of the microelectronic device substrate.

The invention further provides a method for removing residue from a surface of a microelectronic device substrate, the method comprising (i) contacting the surface of the microelectronic device substrate with a composition comprising (a) water, (b) a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof, (c) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, (d) a pH adjustor, and (e) a reducing agent selected from diethyl hydroxylamine, ascorbic acid, hypophosphorous acid, sulfurous acid, salts thereof, and combinations thereof, and (ii) removing at least a portion of the residue from the surface of the microelectronic device substrate.

The invention further provides a method for removing residue from a surface of a microelectronic device substrate, the method comprising (i) contacting the surface of the microelectronic device substrate with a composition comprising (a) water, (b) a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof, (c) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, (d) a pH adjustor, and (e) a corrosion inhibitor selected from dicyandiamide, morpholine, guanylurea, glycocyamine, salts thereof, and combinations thereof, and (ii) removing at least a portion of the residue from the surface of the microelectronic device substrate.

The invention further provides a method for removing residue from a surface of a microelectronic device substrate, the method comprising (i) contacting the surface of the microelectronic device substrate with a composition comprising (a) water, (b) a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof, (c) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, (d) a pH adjustor, and (e) a water-miscible solvent selected from triethylene glycol monobutyl ether, propylene glycol n-butyl ether, propylene glycol monobutyl ether, dimethyl sulfoxide, diethylene glycol monophenyl ether, diethylene glycol monobutyl ether, and combinations thereof, and (ii) removing at least a portion of the residue from the surface of the microelectronic device substrate.

Aspects, including embodiments, of the invention described herein may be beneficial alone or in combination, with one or more other aspects or embodiments. Without limiting the foregoing description, certain non-limiting embodiments of the disclosure numbered 1-30 are provided below. As will be apparent to those of skill in the art upon reading this disclosure, each of the individually numbered embodiments may be used or combined with any of the preceding or following individually numbered embodiments. This is intended to provide support for all such combinations of embodiments and is not limited to combinations of embodiments explicitly provided below:

### EMBODIMENTS

(1) In embodiment (1) is presented a composition comprising:
(a) water,
(b) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and
(c) a pH adjustor.

(2) In embodiment (2) is presented the composition of embodiment (1), wherein the composition further comprises a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof.

(3) In embodiment (3) is presented the composition of embodiment (1) or embodiment (2), wherein the composition further comprises a reducing agent selected from diethyl hydroxylamine, ascorbic acid, hypophosphorous acid, sulfurous acid, salts thereof, and combinations thereof.

(4) In embodiment (4) is presented the composition of embodiment (3), wherein the reducing agent is selected from diethyl hydroxylamine, ascorbic acid, hypophosphorous acid, salts thereof, and combinations thereof.

(5) In embodiment (5) is presented the composition of embodiment (4), wherein the reducing agent is diethyl hydroxylamine.

(6) In embodiment (6) is presented the composition of any one of embodiments (1)-(5), wherein the composition further comprises a corrosion inhibitor selected from dicyandiamide, morpholine, guanylurea, glycocyamine, salts thereof, and combinations thereof.

(7) In embodiment (7) is presented the composition of any one of embodiments (1)-(6), wherein the pH adjustor is selected from choline hydroxide, potassium hydroxide, tetraethylammonium hydroxide, methyl tris (hydroxyethyl)ammonium hydroxide, salts thereof, and combinations thereof.

(8) In embodiment (8) is presented the composition of embodiment (7), wherein the pH adjustor is choline hydroxide.

(9) In embodiment (9) is presented the composition of any one of embodiments (1)-(8), wherein the composition further comprises one or more additional complexing agents selected from glycine, alanine, serine, arginine, histidine, lysine, glutamic acid, serine, threonine, proline, 1-hydroxyethylidene-1,1-diphosphonic acid, 1,5,9-triazacyclododecane-N,N′,N″-tris(methylenephosphonic acid), 1,4,7,10-tetraazacyclododecane-N,N′,N″,N′″-tetrakis(methylenep-hosphonic acid), nitrilotris(methylene)triphosphonic acid, diethylenetriaminepentakis(methylenephosphonic acid), aminotri(methylenephosphonic acid), bis(hexamethylene)triamine pentamethylene phosphonic acid, 1,4,7-triazacyclononane-N,N′,N″-tris(methylenephosphonic acid, hydroxyethyldiphosphonate, nitrilotris(methylene)phosphonic acid, 2-phosphono-butane-1,2,3,4-tetracarboxylic acid, carboxyethyl phosphonic acid, aminoethyl phosphonic acid, glyphosate; ethylene diamine tetra(methylenephosphonic acid) phenylphosphonic acid, oxalic acid, succinic acid, maleic acid, malic acid, malonic acid, adipic acid, phthalic acid, citric acid, tricarballylic acid, dimethylolpropionic acid, trimethylolpropionic acid, tartaric acid, glucuronic acid, 2-carboxypyridine, 4,5-dihydroxy-1,3-benzenedisulfonic acid, and salts thereof.

(10) In embodiment (10) is presented the composition of any one of embodiments (1)-(9), wherein the composition further comprises one or more water-miscible solvents.

(11) In embodiment (11) is presented the composition of embodiment (10), wherein the water-miscible solvent is selected from triethylene glycol monobutyl ether, propylene glycol n-butyl ether, propylene glycol monobutyl ether, dimethyl sulfoxide, diethylene glycol monophenyl ether, diethylene glycol monobutyl ether, and combinations thereof.

(12) In embodiment (12) is presented the composition of any one of embodiments (1)-(11), wherein the composition further comprises one or more surfactants, for example polyethylene glycol.

(13) In embodiment (13) is presented the composition of any one of embodiments (1)-(12), wherein the composition further comprises one or more water-dispersible or water-soluble polymers.

(14) In embodiment (14) is presented the composition of any one of embodiments (1)-(13), wherein the composition has a pH of 8 to 14.

(15) In embodiment (15) is presented the composition of embodiment (14), wherein the composition has a pH of 11 to 14.

(16) In embodiment (16) is presented a method for removing residue from a surface of a microelectronic device substrate, the method comprising:
(i) contacting the surface of the microelectronic device substrate with a composition comprising:
   (a) water,
   (b) a chelating agent selected from multifunctional alcohol poly(oxypropylene)polyamine (e.g., glyceryl poly(oxypropylene)triamine), 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and
   (c) a pH adjustor, and
(ii) removing at least a portion of the residue from the surface of the microelectronic device substrate.

(17) In embodiment (17) is presented the method of embodiment (16), wherein the composition further comprises a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof.

(18) In embodiment (18) is presented the method of embodiment (16) or embodiment (17), wherein the composition further comprises a reducing agent selected from diethyl hydroxylamine, ascorbic acid, hypophosphorous acid, sulfurous acid, salts thereof, and combinations thereof.

(19) In embodiment (19) is presented the method of embodiment (18), wherein the reducing agent is selected from diethyl hydroxylamine, ascorbic acid, hypophosphorous acid, salts thereof, and combinations thereof.

(20) In embodiment (20) is presented the method of embodiment (19), wherein the reducing agent is diethyl hydroxylamine.

(21) In embodiment (21) is presented the method of any one of embodiments (16)-(20), wherein the composition further comprises a corrosion inhibitor selected from dicyandiamide, morpholine, guanylurea, glycocyamine, salts thereof, and combinations thereof.

(22) In embodiment (22) is presented the method of any one of embodiments (16)-(21), wherein the pH adjustor is selected from choline hydroxide, potassium hydroxide, tetraethylammonium hydroxide, methyl tris (hydroxyethyl)ammonium hydroxide, salts thereof, and combinations thereof.

(23) In embodiment (23) is presented the method of embodiment (22), wherein the pH adjustor is choline hydroxide.

(24) In embodiment (24) is presented the method of any one of embodiments (16)-(23), wherein the composition further comprises one or more additional complexing agents selected from glycine, alanine, serine, arginine, histidine, lysine, glutamic acid, serine, threonine, proline, 1-hydroxyethylidene-1,1-diphosphonic acid, 1,5,9-triazacyclododecane-N,N′,N″-tris(methylenephosphonic acid), 1,4,7,10-tetraazacyclododecane-N,N′,N″,N′″-tetrakis(methylenep-hosphonic acid), nitrilotris(methylene)triphosphonic acid, diethylenetriaminepentakis(methylenephosphonic acid), aminotri(methylenephosphonic acid), bis(hexamethylene)triamine pentamethylene phosphonic acid, 1,4,7-triazacyclononane-N,N′,N″-tris(methylenephosphonic acid, hydroxyethyldiphosphonate, nitrilotris(methylene)phosphonic acid, 2-phosphono-butane-1,2,3,4-tetracarboxylic acid, carboxyethyl phosphonic acid, aminoethyl phosphonic acid, glyphosate; ethylene diamine tetra(methylenephosphonic acid) phenylphosphonic acid, oxalic acid, succinic acid, maleic acid, malic acid, malonic acid, adipic acid, phthalic acid, citric acid, tricarballylic acid, dimethylolpropionic acid, trimethylolpropionic acid, tartaric acid, glucuronic acid, 2-carboxypyridine, 4,5-dihydroxy-1,3-benzenedisulfonic acid, and salts thereof.

(25) In embodiment (25) is presented the method of any one of embodiments (16)-(24), wherein the composition further comprises one or more water-miscible solvents.

(26) In embodiment (26) is presented the method of embodiment (25), wherein the water-miscible solvent is selected from triethylene glycol monobutyl ether, propylene glycol n-butyl ether, propylene glycol monobutyl ether, dimethyl sulfoxide, diethylene glycol monophenyl ether, diethylene glycol monobutyl ether, and combinations thereof.

(27) In embodiment (27) is presented the method of any one of embodiments (16)-(26), wherein the composition further comprises one or more surfactants.

(28) In embodiment (28) is presented the method of any one of embodiments (16)-(27), wherein the composition further comprises one or more water-dispersible or water-soluble polymers.

(29) In embodiment (29) is presented the method of any one of embodiments (16)-(28), wherein the composition has a pH of 8 to 14.

(30) In embodiment (30) is presented the method of embodiment (29), wherein the composition has a pH of 11 to 14.

### EXAMPLES

These following examples further illustrate the invention but, of course, should not be construed as in any way limiting its scope.

In the following Examples 1-3, X-ray fluorescence (XRF) was employed to determine the copper and cobalt film thicknesses before and after a post chemical-mechanical planarization (CMP) cleaning process. The copper and cobalt etch rates were calculated using the change in film thickness as a function of time. In addition, benzotriazole (BTA) was applied to a copper surface and measured by ellipsometry. The BTA removal rate was estimated as the change in BTA film thickness as a function of post chemical-mechanical planarization (CMP) cleaning process time.

### Example 1

This example demonstrates the effect of chelating agent on the cleaning performance of a composition prepared according to the invention.

Cleaning Compositions 1A-1I containing water, L-cysteine (0.03 wt. %), 45% potassium hydroxide (5.1 wt. %), and the chelating agents (i.e., monoethanolamine, glyceryl poly(oxypropylene)triamine (JEFFAMINE™ T-5000 Polyetheramine, commercially available from Hunstman), 2-dimethylaminoethanol (CAS #108-01-0), triethanolamine (CAS #102-71-6, ), N,N,N′N′-tetramethyl-2,2′-oxybis(ethylamine) (CAS #3033-62-3), glyceryl poly(oxypropylene)triamine (JEFFAMINE™ ST-404 Polyetheramine, commercially available from Hunstman), cyclohexyldimethylamine (JEFFCAT™ DMCHA, CAS #98-94-2, commercially available from Hunstman), 3-butoxypropylamine (JEFFADD™ MW-781, CAS #16499-88-0, commercially available from Hunstman), and 4-[2-(2-hydroxyethoxy)ethyl]morpholine (CAS #3603-45-0) in the amounts set forth in Table 1 were prepared and used to clean polished 300 mm copper blanket wafers containing a cobalt barrier layer. Cleaning Compositions 1A-1I were diluted 60-fold with deionized water at the point-of-use.

TABLE 1
Cleaning Compositions 1A-1I

| | | | | Conduc- |
|---|---|---|---|---|
| Cleaning | water | Chelating agent | | tivity |
| Composition | (wt. %) | (wt. %) | pH | (mS/cm) |
| 1A | 93.6 | Monoethanolamine (1.26) | 13.5 | 90 |
| (Comparative) | | | | |
| 1B | 89.9 | JEFFAMINE ™ T-5000 | 13.6 | 83 |
| (Inventive) | | Polyetheramine (4.99) | | |
| 1C | 93.0 | 2-dimethylaminoethanol | 13.5 | 88 |
| (Inventive) | | (1.84) | | |
| 1D | 91.8 | triethanolamine (3.05) | 13.4 | 78 |
| (Comparative) | | | | |
| 1E | 91.6 | N,N,N′N′-tetramethyl-2,2′- | 13.5 | 90 |
| (Inventive) | | oxybis(ethylamine) (3.30) | | |
| 1F | 90.4 | glyceryl | 13.6 | 83 |
| (Inventive) | | poly(oxypropylene)triamine | | |
| | | (4.48) | | |
| 1G | 92.3 | cyclohexyldimethylamine | 13.5 | 93 |
| (Inventive) | | (2.61) | | |
| 1H | 92.2 | 3-butoxypropylamine (2.69) | 13.6 | 86 |
| (Inventive) | | | | |
| 1I | 91.3 | 4-[2-(2- | 13.5 | 86 |
| (Inventive) | | hydroxyethoxy)ethyl]mor- | | |
| | | pholine (3.58) | | |

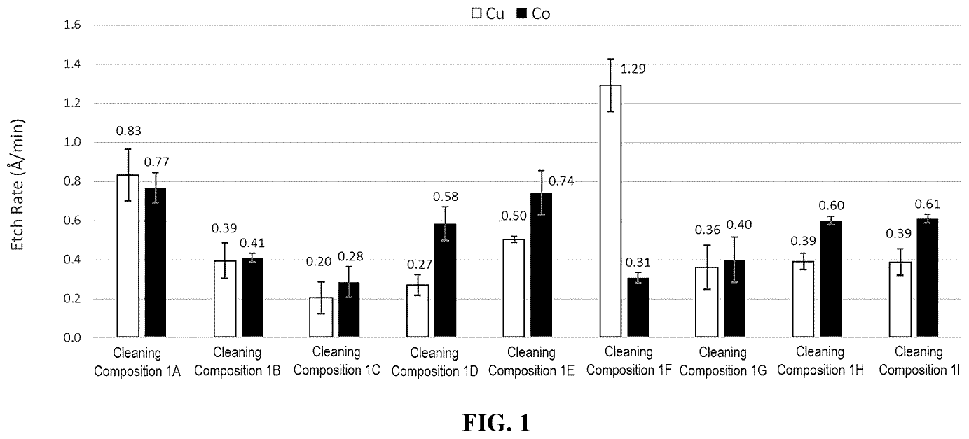

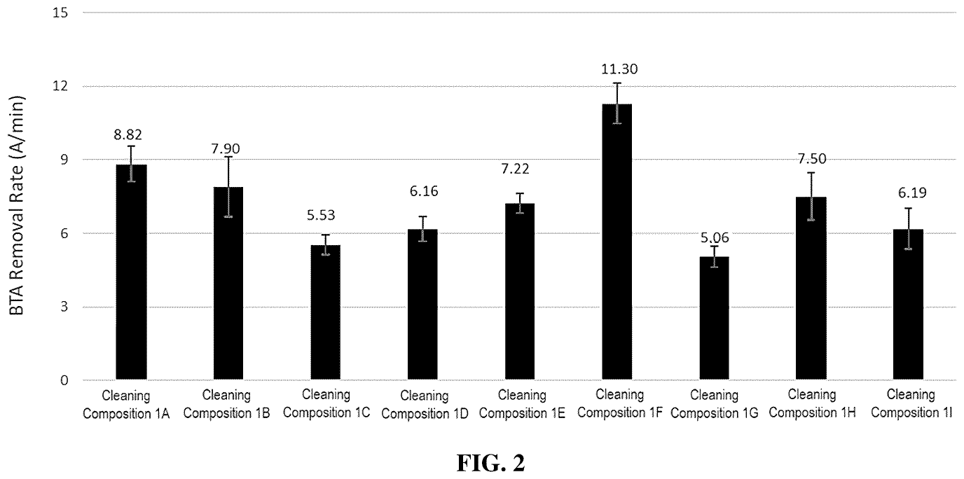

The copper (Cu) etch rate, cobalt (Co) etch rate, and benzotriazole (BTA) removal rate were measured and the results are set forth in Table 2. In addition, the copper (Cu) etch rate and cobalt (Co) etch rate are plotted in FIG. 1 and the benzotriazole (BTA) removal rate is plotted in FIG. 2.

TABLE 2
Composition Cleaning Rates of Cleaning Compositions
1A-1I as a Function of Chelating Agent

| Cleaning | Cu Etch Rate | Co Etch Rate | BTA Removal |
|---|---|---|---|
| Composition | (Å/min) | (Å/min) | Rate (Å/min) |
| 1A (Comparative) | 0.83 | 0.77 | 8.82 |
| 1B (Inventive) | 0.39 | 0.41 | 7.90 |
| 1C (Inventive) | 0.20 | 0.28 | 5.53 |
| 1D (Comparative) | 0.27 | 0.58 | 6.16 |
| 1E (Inventive) | 0.50 | 0.74 | 7.22 |
| 1F (Inventive) | 1.29 | 0.31 | 11.30 |
| 1G (Inventive) | 0.36 | 0.40 | 5.06 |
| 1H (Inventive) | 0.39 | 0.60 | 7.50 |
| 1I (Inventive) | 0.39 | 0.61 | 6.19 |

As is apparent from the results set forth in Table 2 and FIGS. 1 and 2, Inventive Cleaning Compositions 1B, 1C, and IE-1I generally exhibited a lower copper etch rate and a lower cobalt etch rate than Comparative Cleaning Composition 1A, which contained monoethanolamine as a chelating agent, while maintaining a BTA removal rate similar to or higher than Comparative Cleaning Composition 1D, which contained triethanolamine as a chelating agent. Thus, this example illustrates the effectiveness of the claimed chelating agents on the cleaning performance of the disclosed compositions.

### Example 2

This example demonstrates the effect of chelating agent, including additional components, on the cleaning performance of a composition prepared according to the invention.

Cleaning Compositions 2A-2D containing water, morpholine (approximately 4.8 wt. %), L-cysteine (approximately 0.03 wt. %), oxalic acid (approximately 0.18 wt. %), 46.7% choline hydroxide (approximately 18.2 wt. %), and the chelating agents (i.e., monoethanolamine, glyceryl poly(oxypropylene)triamine (JEFFAMINE™ T-5000 Polyetheramine, commercially available from Hunstman), 2-dimethylaminoethanol (CAS #108-01-0), and triethanolamine (CAS #102-71-6) in the amounts set forth in Table 3 were prepared and used to clean polished 300 mm copper blanket wafers containing a cobalt barrier layer.

In addition, Cleaning Compositions 2E-2H containing water, 3% dicyandiamide solution (approximately 6.7 wt. %), L-cysteine (approximately 0.03 wt. %), triethylene glycolmonobutyl ether (approximately 0.6 wt. %), 46.7% choline hydroxide (approximately 15 wt. %), and the chelating agents (i.e., monoethanolamine, glyceryl poly(oxypropylene)triamine (JEFFAMINE™ T-5000 Polyetheramine, i.e., XTJ-669, commercially available from Hunstman), 2-dimethylaminoethanol (CAS #108-01-0, i.e., XHE-129), and triethanolamine (CAS #102-71-6, i.e., XHE-130)) in the amounts set forth in Table 3 were prepared and used to clean polished 300 mm copper blanket wafers containing a cobalt barrier layer. Cleaning Compositions 2A-2H were diluted 60-fold with deionized water at the point-of-use.

TABLE 3
Cleaning Compositions 2A-2H

| | water | | | Conduc- |
|---|---|---|---|---|
| Cleaning | (wt. | Chelating agent | | tivity |
| Composition | %) | (wt. %) | pH | (mS/cm) |
| 2A (Comparative) | 75.6 | Monoethanolamine (1.15) | 13.7 | 44 |
| 2B (Inventive) | 72.3 | JEFFAMINE ™ T-5000 | 13.7 | 39 |
| | | Polyetheramine (4.56) | | |
| 2C (Inventive) | 75.1 | 2-dimethylaminoethanol | 13.6 | 44 |
| | | (1.64) | | |
| 2D (Comparative) | 74.0 | triethanolamine (2.78) | 13.6 | 41 |
| 2E (Comparative) | 76.4 | Monoethanolamine | 13.5 | 48 |
| | | (1.26) | | |
| 2F (Inventive) | 72.7 | JEFFAMINE ™ T-5000 | 13.6 | 43 |
| | | Polyetheramine (4.98) | | |
| 2G (Inventive) | 75.8 | 2-dimethylaminoethanol | 13.5 | 48 |
| | | (1.83) | | |
| 2H (Comparative) | 74.6 | triethanolamine (3.05) | 13.4 | 43 |

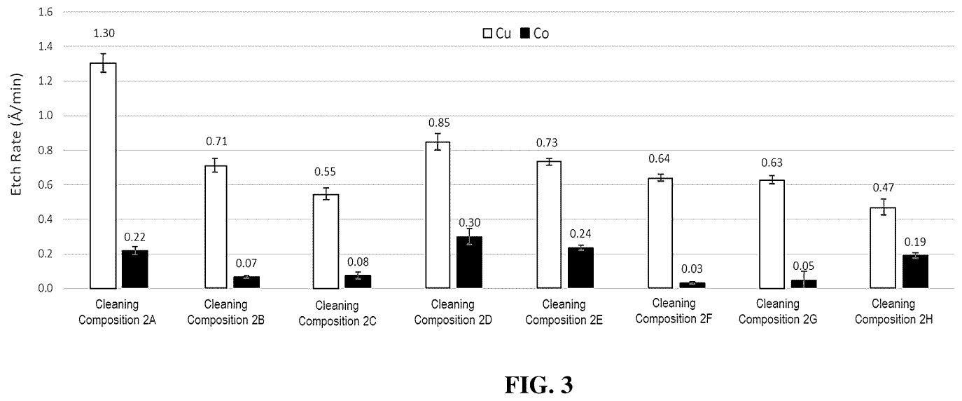

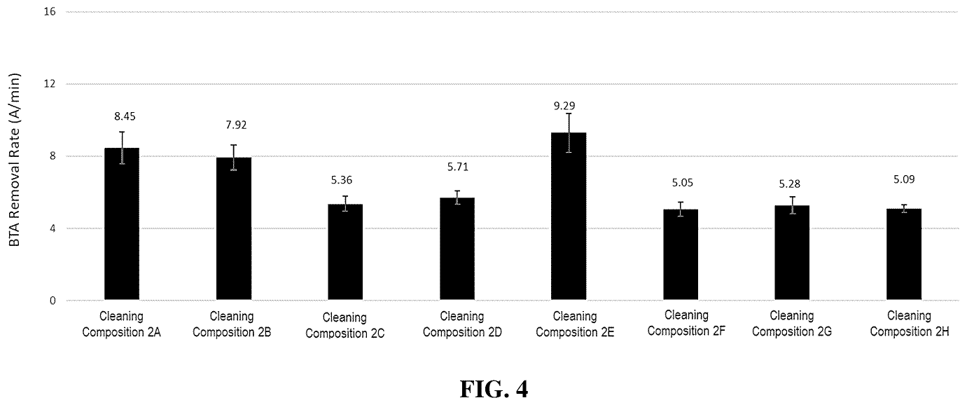

The copper (Cu) etch rate, cobalt (Co) etch rate, and benzotriazole (BTA) removal rate were measured and the results are set forth in Table 4. In addition, the copper (Cu) etch rate and cobalt (Co) etch rate are plotted in FIG. 3 and the benzotriazole (BTA) removal rate is plotted in FIG. 4.

TABLE 4
Composition Cleaning Rates of Cleaning Compositions
2A-2H as a Function of Chelating Agent

| Cleaning | Cu Etch Rate | Co Etch Rate | BTA Removal |
|---|---|---|---|
| Composition | (Å/min) | (Å/min) | Rate (Å/min) |
| 2A (Comparative) | 1.3 | 0.22 | 8.45 |
| 2B (Inventive) | 0.71 | 0.07 | 7.92 |
| 2C (Inventive) | 0.55 | 0.08 | 5.36 |
| 2D (Comparative) | 0.85 | 0.30 | 5.71 |
| 2E (Comparative) | 0.73 | 0.24 | 9.29 |
| 2F (Inventive) | 0.64 | 0.03 | 5.05 |
| 2G (Inventive) | 0.63 | 0.05 | 5.28 |
| 2H (Comparative) | 0.47 | 0.19 | 5.09 |

As is apparent from the results set forth in Table 4 and FIGS. 3 and 4, Inventive Cleaning Compositions 2B, 2C, 2F, and 2G exhibited a lower copper etch rate and a lower cobalt etch rate than Comparative Cleaning Compositions 2A and 2E, containing monoethanolamine as a chelating agent, while maintaining a BTA removal rate that is similar to or higher than Comparative Cleaning Compositions 2D and 2H, containing triethanolamine as a chelating agent. Thus, this example illustrates the effectiveness of the claimed chelating agents on the cleaning performance of the disclosed compositions.

### Example 3

This example demonstrates the effect of chelating agent concentration, in the absence of dicyandiamide corrosion inhibitor, on the cleaning performance of a composition prepared according to the invention.

Cleaning Compositions 3A-3H containing water, L-cysteine (approximately 0.03 wt. %), triethylene glycolmonobutyl ether (approximately 0.6 wt. %), 46.7% choline hydroxide (approximately 15 wt. %), and the chelating agents; monoethanolamine, glyceryl poly(oxypropylene)triamine (JEFFAMINE™ T-5000 Polyetheramine, commercially available from Hunstman), 2-dimethylaminoethanol (CAS #108-01-0), and methyl monoethanolamine (CAS #109-83-1) in the amounts set forth in Table 5 were prepared and used to clean polished 300 mm copper blanket wafers containing a cobalt barrier layer. Cleaning Compositions 3A-3H were diluted 60-fold with deionized water at the point-of-use.

TABLE 5
Cleaning Compositions 3A-3H

| | water | | | Conduc- |
|---|---|---|---|---|
| Cleaning | (wt. | Chelating agent | | tivity |
| Composition | %) | (wt. %) | pH | (mS/cm) |
| 3A | 76.4 | Monoethanolamine (1.26) | 13.4 | 48 |
| (Comparative)* | | | | |
| 3B (Comparative) | 83.1 | Monoethanolamine (1.26) | 13.4 | 49 |
| 3C (Inventive) | 79.4 | JEFFAMINE ™ T-5000 | 13.5 | 43 |
| | | Polyetheramine (4.98) | | |
| 3D (Inventive) | 81.9 | JEFFAMINE ™ T-5000 | 13.4 | 47 |
| | | Polyetheramine (2.49) | | |
| 3E (Inventive) | 82.5 | 2-dimethylaminoethanol | 13.4 | 48 |
| | | (1.84) | | |
| 3F (Inventive) | 83.4 | 2-dimethylaminoethanol | 13.4 | 49 |
| | | (0.92) | | |
| 3G (Comparative) | 82.8 | Methyl monoethanolamine | 13.4 | 48 |
| | | (1.53) | | |
| 3H (Comparative) | 83.6 | Methyl monoethanolamine | 13.4 | 49 |
| | | (0.77) | | |

*Further contained 3% dicyandiamide solution (approximately 6.7 wt. %)

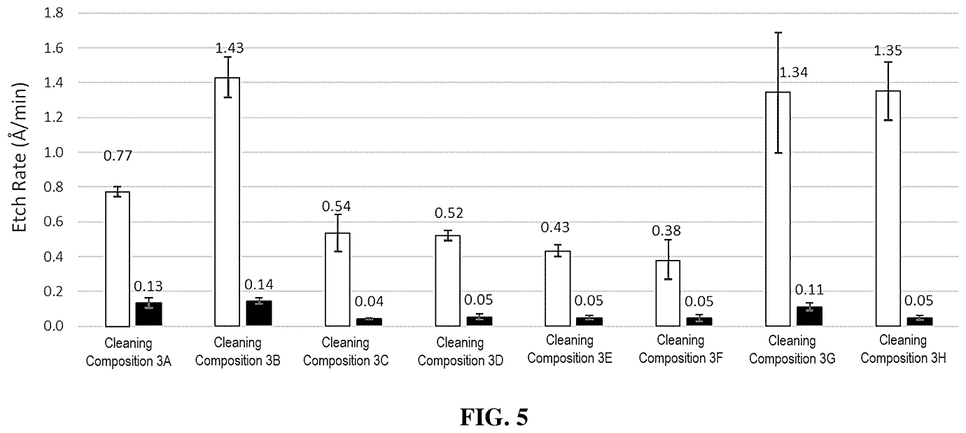

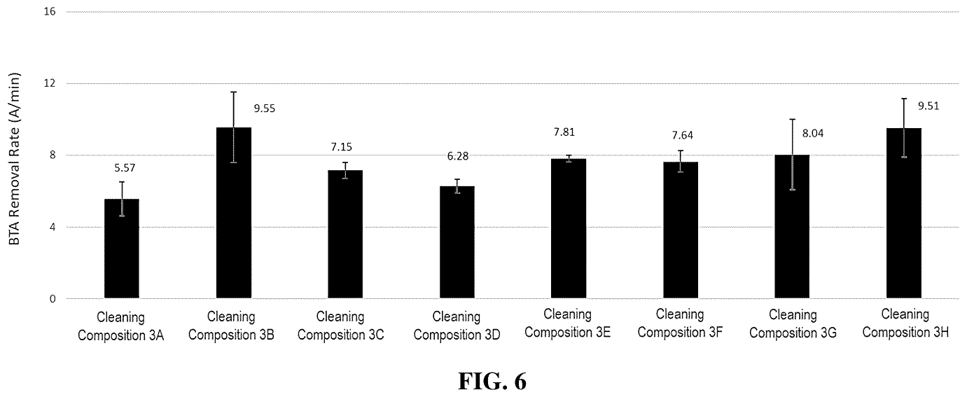

The copper (Cu) etch rate, cobalt (Co) etch rate, and benzotriazole (BTA) removal rate were measured and the results are set forth in Table 6. In addition, the copper (Cu) etch rate and cobalt (Co) etch rate are plotted in FIG. 5 and the benzotriazole (BTA) removal rate is plotted in FIG. 6.

TABLE 6
Composition Cleaning Rates of Cleaning Compositions
3A-3H as a Function of Chelating Agent Concentration

| Cleaning | Cu Etch Rate | Co Etch Rate | BTA Removal |
|---|---|---|---|
| Composition | (Å/min) | (Å/min) | Rate (Å/min) |
| 3A (Comparative) | 0.77 | 0.13 | 5.57 |
| 3B (Comparative) | 1.43 | 0.14 | 9.55 |
| 3C (Inventive) | 0.54 | 0.04 | 7.15 |
| 3D (Inventive) | 0.52 | 0.05 | 6.28 |
| 3E (Inventive) | 0.43 | 0.05 | 7.81 |
| 3F (Inventive) | 0.38 | 0.05 | 7.64 |
| 3G (Comparative) | 1.34 | 0.11 | 8.04 |
| 3H (Comparative) | 1.35 | 0.05 | 9.51 |

As is apparent from the results set forth in Table 6 and FIGS. 5 and 6, Inventive Cleaning Compositions 3C-3F exhibited a lower copper etch rate and a lower cobalt etch rate than Comparative Cleaning Compositions 3A, 3B, 3G, and 3H, which contained monoethanolamine or methyl monoethanolamine as a chelating agent, while maintaining a similar BTA removal rate. In addition, Inventive Cleaning Compositions 3C-3F, which did not contain dicyandiamide, exhibited a lower copper etch rate and a lower cobalt etch rate than Comparative Cleaning Composition 3A, which contained dicyandiamide. Inventive Cleaning Compositions 3C-3F of Table 6 and FIGS. 5 and 6 also show that doubling the concentration of the chelating agent did not have a significant effect on copper etch rate, cobalt etch rate, or BTA removal rate.

### Example 4

This example demonstrates the effect on slurry removal efficiency, as measured by the remaining particle surface area, of a copper polishing silica-based slurry containing benzotriazole (BTA) exhibited by a composition prepared according to the invention.

Cleaning Compositions 4A-4C containing water, L-cysteine (approximately 0.03 wt. %), triethylene glycolmonobutyl ether (approximately 0.6 wt. %), 46.7% choline hydroxide (approximately 15 wt. %), and the chelating agents (i.e., monoethanolamine, glyceryl poly(oxypropylene)triamine (JEFFAMINE™ T-5000 Polyetheramine, commercially available from Hunstman), and 2-dimethylaminoethanol (CAS #108-01-0,) in the amounts set forth in Table 7 were prepared and used to clean 300 mm copper blanket wafers that were polished on a benchtop polisher with a 1^{st} or 2^{nd} copper polishing silica-based slurry containing benzotriazole (BTA). Cleaning Compositions 4A-4C were diluted 60-fold with deionized water at the point-of-use.

TABLE 7
Cleaning Compositions 4A-4C

| | water | | | Conduc- |
|---|---|---|---|---|
| Cleaning | (wt. | Chelating agent | | tivity |
| Composition | %) | (wt. %) | pH | (mS/cm) |
| 4A (Comparative) | 76.4 | Monoethanolamine (1.26) | 13.4 | 48 |
| 4B (Inventive) | 79.4 | JEFFAMINE ™ T-5000 | 13.5 | 43 |
| | | Polyetheramine (4.98) | | |
| 4C (Inventive) | 82.5 | 2-dimethylaminoethanol | 13.4 | 48 |
| | | (1.84) | | |

Scanning electron microscope (SEM) was used to image slurry particles remaining on a copper surface that was polished on a benchtop polisher with a 1^{st} or 2^{nd} copper polishing silica-based slurry containing benzotriazole (BTA), and “particle surface area” was calculated as a measure of slurry cleaning efficiency. A lower remaining “particle surface area” indicates better cleaning efficiency of a cleaning composition. The results of the remaining particle surface area of deionized water (control) and Cleaning Compositions 4A-4C for the 1^{st} and 2^{nd} copper polishing silica-based slurries containing benzotriazole (BTA) are set forth in Table 8.

TABLE 8
Copper Polishing Slurry Removal Efficiency of Cleaning Compositions
4A-4C as a Function of Remaining Particle Surface Area

| | 1^{st} Polishing | 2^{nd} Polishing |
|---|---|---|
| | Composition | Composition |
| Cleaning | Remaining Particle | Remaining Particle |
| Composition | Surface Area (%) | Surface Area (%) |
| Deionized Water (Control) | 1.117 | 0.750 |
| 4A (Comparative) | 0.775 | 1.398 |
| 4B (Inventive) | 0.487 | 0.311 |
| 4C (Inventive) | 0.721 | 0.505 |

As is apparent from the results set forth in Table 8, Inventive Cleaning Compositions 4B and 4C exhibited a lower remaining “particle surface area” than deionized water and Comparative Cleaning Composition 4A for both the 1^{st} and 2^{nd} copper polishing silica-based slurries containing benzotriazole (BTA). In addition, Inventive Cleaning Composition 4B, containing glyceryl poly(oxypropylene)triamine (JEFFAMINE™ T-5000 Polyetheraminecommercially available from Hunstman), outperformed all other cleaning compositions tested for both the 1^{st} and 2^{nd} copper polishing silica-based slurries containing benzotriazole (BTA).

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A composition comprising:
(a) water,
(b) a chelating agent selected from multifunctional alcohol poly(oxypropylene)polyamine, 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and
(c) a pH adjustor.

2. The composition of claim 1, wherein the composition further comprises a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof.

3. The composition of claim 1, wherein the composition further comprises a reducing agent selected from diethyl hydroxylamine, ascorbic acid, hypophosphorous acid, sulfurous acid, salts thereof, and combinations thereof.

4. The composition of claim 1, wherein the composition further comprises a corrosion inhibitor selected from dicyandiamide, morpholine, guanylurea, glycocyamine, salts thereof, and combinations thereof.

5. The composition of claim 1, wherein the pH adjustor is selected from choline hydroxide, potassium hydroxide, tetraethylammonium hydroxide, methyl tris (hydroxyethyl)ammonium hydroxide, salts thereof, and combinations thereof.

6. The composition of claim 5, wherein the pH adjustor is choline hydroxide.

7. The composition of claim 1, wherein the composition further comprises one or more additional complexing agents selected from glycine, alanine, serine, arginine, histidine, lysine, glutamic acid, serine, threonine, proline, 1-hydroxyethylidene1,1-diphosphonic acid, 1,5,9-triazacyclododecane-N,N′,N″-tris(methylenephosphonic acid), 1,4,7,10-tetraazacyclododecane-N,N′,N″,N′″-tetrakis(methylenep-hosphonic acid), nitrilotris(methylene)triphosphonic acid, diethylenetriaminepentakis(methylenephosphonic acid), aminotri(methylenephosphonic acid), bis(hexamethylene)triamine pentamethylene phosphonic acid, 1,4,7-triazacyclononane-N,N′,N″-tris(methylenephosphonic acid, hydroxyethyldiphosphonate, nitrilotris(methylene)phosphonic acid, 2-phosphono-butane-1,2,3,4-tetracarboxylic acid, carboxyethyl phosphonic acid, aminoethyl phosphonic acid, glyphosate; ethylene diamine tetra(methylenephosphonic acid) phenylphosphonic acid, oxalic acid, succinic acid, maleic acid, malic acid, malonic acid, adipic acid, phthalic acid, citric acid, tricarballylic acid, dimethylolpropionic acid, trimethylolpropionic acid, tartaric acid, glucuronic acid, 2-carboxypyridine, 4,5-dihydroxy-1,3-benzenedisulfonic acid, and salts thereof.

8. The composition of claim 1, wherein the composition further comprises one or more water-miscible solvents.

9. The composition of claim 8, wherein the water-miscible solvent is selected from triethylene glycol monobutyl ether, propylene glycol n-butyl ether, propylene glycol monobutyl ether, dimethyl sulfoxide, diethylene glycol monophenyl ether, diethylene glycol monobutyl ether, and combinations thereof.

10. The composition of claim 1, wherein the composition further comprises one or more surfactants.

11. The composition of claim 1, wherein the composition further comprises one or more water-dispersible or water-soluble polymers.

12. The composition of claim 1, wherein the composition has a pH of 8 to 14.

13. A method for removing residue from a surface of a microelectronic device substrate, the method comprising:
(i) contacting the surface of the microelectronic device substrate with a composition comprising:
(a) water,
(b) a chelating agent selected from multifunctional alcohol poly(oxypropylene)polyamine, 2-dimethylaminoethanol, N,N,N′N′-tetramethyl-2,2′-oxybis(ethylamine), 1,1′-(oxybis(ethane-2,1-diyl))dipyrrolidine, cyclohexyldimethylamine, 3-butoxypropylamine, 4-[2-(2-hydroxyethoxy)ethyl]morpholine, salts thereof, and combinations thereof, and
(c) a pH adjustor, and
(ii) removing at least a portion of the residue from the surface of the microelectronic device substrate.

14. The method of claim 13, wherein the composition further comprises a cleaning additive selected from cysteine, cystine, 2-aminothiophenol, 2-thiazoline-2-thiol, 1,3,4-thiadiazole-2-,5-dithiol, 1,3,4-thiadiazole-2-methyl-5-thiol, ethyldithiocarbamate, salts thereof, and combinations thereof.

15. The method of claim 13, wherein the composition further comprises a reducing agent selected from diethyl hydroxylamine, ascorbic acid, hypophosphorous acid, sulfurous acid, salts thereof, and combinations thereof.

16. The method of claim 13, wherein the composition further comprises a corrosion inhibitor selected from dicyandiamide, morpholine, guanylurea, glycocyamine, salts thereof, and combinations thereof.

17. The method of claim 13, wherein the pH adjustor is selected from choline hydroxide, potassium hydroxide, tetraethylammonium hydroxide, methyl tris (hydroxyethyl)ammonium hydroxide, salts thereof, and combinations thereof.

18. The method of claim 13, wherein the composition further comprises one or more additional complexing agents selected from glycine, alanine, serine, arginine, histidine, lysine, glutamic acid, serine, threonine, proline, 1-hydroxyethylidene-1,1-diphosphonic acid, 1,5,9-triazacyclododecane-N,N′,N″-tris(methylenephosphonic acid), 1,4,7,10-tetraazacyclododecane-N,N′,N″,N′″-tetrakis(methylenep-hosphonic acid), nitrilotris(methylene)triphosphonic acid, diethylenetriaminepentakis(methylenephosphonic acid), aminotri(methylenephosphonic acid), bis(hexamethylene)triamine pentamethylene phosphonic acid, 1,4,7-triazacyclononane-N,N′,N″-tris(methylenephosphonic acid, hydroxyethyldiphosphonate, nitrilotris(methylene)phosphonic acid, 2-phosphono-butane-1,2,3,4-tetracarboxylic acid, carboxyethyl phosphonic acid, aminoethyl phosphonic acid, glyphosate; ethylene diamine tetra(methylenephosphonic acid) phenylphosphonic acid, oxalic acid, succinic acid, maleic acid, malic acid, malonic acid, adipic acid, phthalic acid, citric acid, tricarballylic acid, dimethylolpropionic acid, trimethylolpropionic acid, tartaric acid, glucuronic acid, 2-carboxypyridine, 4,5-dihydroxy-1,3-benzenedisulfonic acid, and salts thereof.

19. The method of claim 13, wherein the composition further comprises one or more water-miscible solvents.

20. The method of claim 13, wherein the composition has a pH of 8 to 14.
